(19) United States
(12) Patent Application Publication
(10) Pub. No.: US 2024/0387461 A1
(43) Pub. Date: Nov. 21, 2024

(54) Semiconductor Device Package with Die Stackup and Connection Platform

(71) Applicant: Wester Digital Technologies, Inc., San Jose, CA (US)

(72) Inventors: Rajitha Indla, Nellore (IN); Narayanan Terizhandur V, Bothell, WA (US); Nagesh Vodrahalli, Los Altos, CA (US)

(73) Assignee: Western Digital Technologies, Inc., San Jose, CA (US)

(21) Appl. No.: 18/366,396

(22) Filed: Aug. 7, 2023

Related U.S. Application Data
(60) Provisional application No. 63/503,381, filed on May 19, 2023.

(51) Int. Cl. H01L 25/065; H01L 23/00; H01L 23/498; H10B 80/00

(52) U.S. Cl. CPC H01L 25/0657; H01L 23/49827; H01L 24/48; H10B 80/00; H01L 2224/48165; H01L 2224/48227; H01L 2225/0651; H01L 2225/06548; H01L 2225/06562

(57) ABSTRACT

A semiconductor device package includes a substrate and a stack of semiconductor dies positioned on the substrate that includes a first semiconductor die and a second semiconductor die. First and second platforms are positioned on the substrate such that the stack of semiconductor dies is positioned therebetween. First and second through-vias are electrically connected to the substrate and extending through the respective first and second platforms. A first bond wire electrically connects the first through-via to the first semiconductor die, and a second bond wire electrically connects the second through-via to the second semiconductor die. The through-vias may reduce the required length of the bond wires thereby reducing signal noise and the platforms may vertically space the bond wires from one another to prevent electrical short circuits.

### CROSS-REFERENCE TO RELATED APPLICATIONS

This application claims the benefit of U.S. Provisional Patent Application No. 63/503,381 filed May 19, 2023 entitled “Semiconductor Device Package with Die Stackup and Connection Platform”, which is incorporated by reference herein in its entirety.

### BACKGROUND

The present disclosure generally relates to semiconductor device packages having a stack of dies and, more particularly, to a semiconductor device package including a die stackup and a platform for routing electrical signals to the die stackup.

A Semiconductor package may include a plurality of stacked dies. For example, a semiconductor memory package may include a plurality of semiconductor memory dies and a controller packaged together on a substrate and encapsulated in a molding compound. The memory dies may be stacked, with the memory dies in the stack being electrically coupled to the substrate with respective pluralities of bond wires. The die stack may include a plurality of different sub-stacks arranged one on top of another in a center stacked manner. The substrate includes communication lines or traces that route electrical signals (e.g., power, ground, input/output (IO) signals) between the bond wires and the controller and to external connections. Conventionally, continuous bond wires directly connected to the substrate transmit power and ground signals to each memory die included in a die stack. However, as the length of the bond wires increases, unwanted disturbances in the electrical signals, commonly referred to as noise, transmitted to and from the memory dies increases as well. Additionally, inductance increases as the length of bond wires increases resulting in voltage drops in electrical signals. Furthermore, as pitch between adjacent bond pads on the memory dies decreases, the risk of electrical shorts occurring due to bond wires contacting one another is increased as well. Therefore, there is a need to provide semiconductor device packages configured to reduce the noise in electrical signals transmitted to and from stacked dies and to reduce the risk of electrical shorts.

### SUMMARY

In one embodiment there is a semiconductor device package including a substrate, a stack of semiconductor dies positioned on the substrate and including a first semiconductor die and a second semiconductor die, a first platform positioned on the substrate, a second platform positioned on the substrate opposite the first platform such that the stack of semiconductor dies is positioned between the first and second platforms, a first through-via electrically connected to the substrate and extending through the first platform, a second through-via electrically connected to the substrate and extending through the second platform, a first bond wire electrically connecting the first through-via to the first semiconductor die, and a second bond wire electrically connecting the second through-via to the second semiconductor die.

In some embodiments, the first platform includes a first stepped surface, a second stepped surface vertically offset from the first stepped surface, and a first bond pad exposed at the first stepped surface and electrically connected to the first through-via, and the first through-via extends through the first platform from the first bond pad to the substrate. In some embodiments, the first platform includes a second bond pad exposed at the second stepped surface, and a third through-via electrically connected to the substrate and the second bond pad, and the third through-via extends through the first platform from the second bond pad to the substrate. In some embodiments, the semiconductor device package further includes a third semiconductor die included in the stack of semiconductor dies, the third semiconductor die positioned above the first and second semiconductor dies, and a third bond wire electrically connecting the third semiconductor die to the third through-via.

In some embodiments, at least a portion of the third bond wire is positioned vertically above the first bond wire and does not directly contact the first bond wire. In some embodiments, the first and second platforms include a series of sections stacked one on top of another, each section comprising a conductive layer and a dielectric layer. In some embodiments, the semiconductor device package further includes a bond pad exposed at a surface of the first platform, the first bond wire being electrically connected to the bond pad, and two or more through-vias electrically connected to the bond pad and the substrate. In some embodiments, the first platform has a total height that is greater than the second platform.

In some embodiments, the first platform and second platform are comprised of a material the same as the substrate. In some embodiments, the stack of semiconductor dies comprise memory dies. In some embodiments, the semiconductor device package further includes a substrate bond pad electrically connected to the substrate and positioned between the stack of semiconductor dies and the first platform, and a bond wire electrically connecting the substrate bond pad to a bottom most semiconductor die included in the stack of semiconductor dies. In some embodiments, the first bond wire is electrically connected to the first semiconductor die and another semiconductor die adjacent to the first semiconductor die. In some embodiments, the first bond wire is electrically connected to the first semiconductor die and at least two adjacent semiconductor dies.

In another embodiment there is a semiconductor device package including a substrate including a top surface and a bond pad exposed at the top surface, a stack of semiconductor dies positioned on the top surface of the substrate, a first platform positioned on the top surface of the substrate, the first platform including a plurality of through-vias electrically connected to the substrate and extending through the first platform, a second platform positioned on the top surface of the substrate opposite the first platform such that the stack of semiconductor dies is positioned between the first and second platforms, the second platform including a plurality of through-vias electrically connected to the substrate and extending through the second platform, and a first bond wire connecting a first semiconductor die of the stack to the at least one through-via of the first platform, and a second bond wire connecting a second semiconductor die of the stack to the at least one through-via of the second platform.

In some embodiments, the first platform includes at least two stepped surfaces vertically offset from one another, each of the stepped surfaces including a bond pad electrically connected to one or more of the plurality of through-vias of the first platform. In some embodiments, at least one of the bond pads there is connected to two or more of the plurality of through-vias of the first platform. In some embodiments, the first and second platforms include a series of sections stacked one on top of another, each section comprising a conductive layer and a dielectric layer. In some embodiments, each through-via of the plurality of through-vias has a diameter of about 10 microns. In some embodiments, the first platform and second platform are comprised of a material the same as the substrate.

In another embodiment there is a semiconductor device package including a substrate means for providing electrical interconnections between electrical components coupled to the substrate means, a first platform means for providing a first set of elevated electrical contacts spaced away from the substrate means, the first platform means include a first conduction means extending through the first platform means for electrically connecting the first set of elevated electrical contacts to the substrate means, a second platform means providing a second set of elevated electrical contacts spaced away from the substrate means, the second platform means including a second conduction means extending through the second platform means for electrically connecting the second set of elevated contacts to the substrate means, and a stack of storage means each for storing an amount of data, the stack of storage means positioned on the substrate means between the first platform means and the second platform means, the stack of storage means including a first storage means electrically connected to the first set of elevated electrical contacts, and a second storage means electrically connected to the second set of elevated electrical contacts.

### BRIEF DESCRIPTION OF THE DRAWINGS

The foregoing summary, as well as the following detailed description, will be better understood when read in conjunction with the appended drawings. For the purpose of illustrating the present disclosure, there are shown in the drawings embodiments, which are presently preferred, wherein like reference numerals indicate like elements throughout. It should be noted, however, that aspects of the present disclosure can be embodied in different forms and thus should not be construed as being limited to the illustrated embodiments set forth herein. The elements illustrated in the accompanying drawings are not necessarily drawn to scale, but rather, may have been exaggerated to highlight the important features of the subject matter therein. Furthermore, the drawings may have been simplified by omitting elements that are not necessarily needed for the understanding of the disclosed embodiments.

In the Drawings:

FIG. 1A is a side cross-sectional view of a portion of a semiconductor device package with a die stackup and platform in accordance with an exemplary embodiment of the present disclosure;

FIG. 1B is a perspective view of the semiconductor device package of FIG. 1A;

FIG. 2 is a side cross-sectional view of a portion of a semiconductor device package with a die stackup and platform in accordance with another exemplary embodiment of the present disclosure; and

FIG. 3 is a side cross-sectional view of a portion of a semiconductor device package with a die stackup and platform in accordance with another exemplary embodiment of the present disclosure.

### DETAILED DESCRIPTION

The present subject matter will now be described more fully hereinafter with reference to the accompanying Figures, in which representative embodiments are shown. The present subject matter can, however, be embodied in different forms and should not be construed as limited to the embodiments set forth herein. Rather, these embodiments are provided to describe and enable one of skill in the art.

Numerous details are described herein in order to provide a thorough understanding of the example embodiments illustrated in the accompanying drawings. However, some embodiments may be practiced without any of the specific details, and the scope of the claims is only limited by those features and aspects specifically recited in the claims. Furthermore, well-known methods, components, and circuits have not be described in exhaustive detail so as not to unnecessarily obscure pertinent aspects of the embodiments described herein.

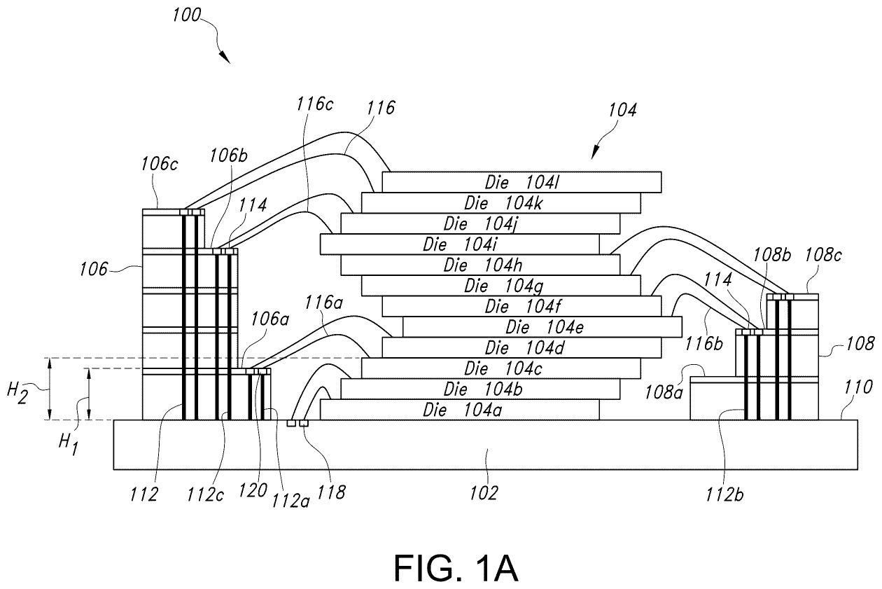

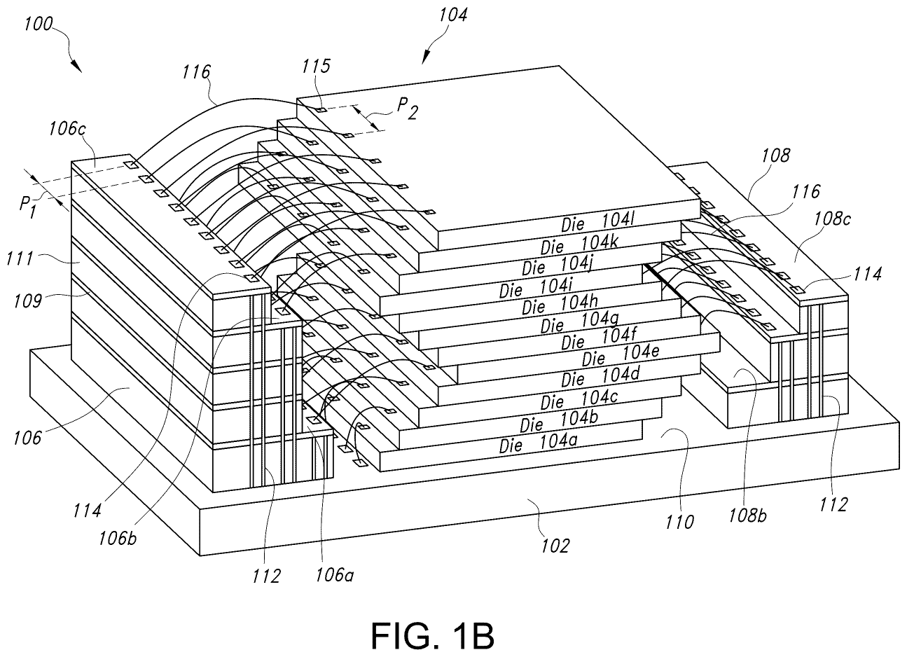

Referring to FIGS. 1A-1B, there is shown a portion of a semiconductor device package, generally designated 100, in accordance with an exemplary embodiment of the present disclosure. The semiconductor device package 100, or package 100 for short, may include a substrate 102, a stack of semiconductor dies 104, a first platform 106 and a second platform 108. The package 100 may be any type of semiconductor device package, such as, but not limited to, a system-in-package (SiP), a storage device (e.g., a secure digital (SD) card or a MultiMediaCard (MMC)). In some embodiments, the stack of semiconductor dies 104 may be a stack of memory dies. The memory dies included in the stack of memory dies 104 may be NAND memory dies. The memory dies included in the stack 104 may generally be storage means configured to store an amount of electrical charge (e.g., provide a data storage amount). In some embodiments, the package 100 may include a controller (not shown) configured to control the routing of signals (e.g., power, ground, IO signals) to and from the semiconductor dies included in the stack 104. In some embodiments, the controller (not shown) may be an application-specific integrated circuit (ASIC), or any other type of controller. The controller may be electrically connected to the substrate 102. In some embodiments, a mold compound (not shown) may encapsulate at least the die stack 104, first platform 106 and second platform 108. The mold compound may include, for example, an epoxy molding compound (EMC) or other encapsulant material known in the art.

The substrate 102 may be a mechanical base support of package 100 and/or an electrical interface that provides access to the stack of semiconductor dies 104 housed within the package. The electrical interface may include a plurality of metal layers within the substrate 102, including at least one layer for routing data using conductive (e.g., copper) traces, a ground layer, and/or a power layer. The stack of semiconductor dies 104 and platforms 106, 108 may be mounted on the top planar surface 110 of the substrate 102. In some embodiments, the stack of semiconductor dies 104, the first platform 106, and second platform 108 may extend from the top planar surface 110 of the substrate 102 (e.g., in an upward direction as depicted in the drawings). The stack of semiconductor dies 104 may be positioned on the substrate 102 between the first platform 106 and second platform 108. For example, in some embodiments, the first platform 106 is positioned on the substrate 102 and spaced from the stack 104 and the second platform 108 may be positioned on the substrate 102 opposite the first platform 106 and spaced from the stack 104. In this manner, there may be a platform (e.g., platform 106, platform 108) spaced from opposing sides of the stack 104.

The stack of semiconductor dies 104 may include a plurality of semiconductor dies including a first (bottom) die on substrate 102, and each subsequent die being stacked thereon on top of an adjacent die. For example, and as illustrated in FIGS. 1A-1B, the stack 104 includes twelve semiconductor dies 104a-1041 stacked one on top of another. In some embodiments, each memory die included in the stack 104 are offset from an adjacent memory die in the longitudinal direction. For example, the stack 104 may be a stack of staggered memory dies and the memory dies included in the stack 104 form a staggered staircase like pattern in which a sidewall of each memory die is offset from a corresponding sidewall of an adjacent memory die. As such, each memory die included in the stack 104 may have an exposed top surface that is not covered by an adjacent memory die where the corresponding set of die bond pads 110 is positioned.

In some embodiments, the semiconductor dies 104a-1041 are arranged in a center stacked or side-by-side stacked pattern. In some embodiments, the semiconductor dies 104a-1041 may form sub-stacks that are aligned along different axes (axes lines not shown). These axes may be obliquely oriented relative to the top planar surface 110 of substrate 102. For example, semiconductor dies 104a-104d may form a first sub-stack of dies, semiconductor dies 104e-104h may form a second sub-stack of dies, and semiconductor dies 104i-104l may form a third sub-stack thereof. A center point of each die included in a respective sub-stack may be positioned generally along an axis (not shown). The axis for the second sub-stack may intersect the axes for the first and third sub-stacks. The axes for the first and third sub-stacks may be generally parallel and offset from one another. Although the axes are not illustrated so as not to clutter the figures, it should be understood that the respective axes may be illustrated as extending through a generally center point of each die included in the above mentioned sub-stacks. In some embodiments, the different sub-stacks of semiconductor dies 104a-104l may alternatively be referred to as different memory channels (e.g., first, second and third memory channels). In some embodiments, the semiconductor dies of a sub-stack may be electrically connected to each other, whereas the semiconductor dies of one sub-stack may be electrically isolated from the semiconductor dies of a different sub-stack. In other embodiments, the semiconductor dies of one sub-stack may be electrically connected to the semiconductor dies of a different sub-stack. In some embodiments, each sub-stack of semiconductor dies may include, for example, at least four semiconductor dies. In some embodiments, the stack of semiconductor dies 104 may include eight or more semiconductor dies. In some embodiments, the stack of semiconductor dies 104 includes at least twelve semiconductor dies. In some embodiments, the stack of semiconductor dies 104 includes at least sixteen semiconductor dies.

The first platform 106 and second platform 108 may each be configured to provide one or more elevated surfaces that are spaced from the top planar surface 110 of substrate 102 to facilitate electrical connections between one or more of the semiconductor dies 104a-104l and the substrate 102. As will be described further below, in some embodiments, first platform 106 and/or second platform 108 may include two or more tiers or “steps,” each step providing a separate elevated surface (“stepped surface”) that is spaced a predetermined distance from the top planar surface 110 of substrate 102. In some embodiments, the first platform 106 and the second platform 108 may have a different number of steps or the same number of steps. Each stepped surface of a single platform may have a different height measured from the top planar surface 110 of substrate 102, according to some embodiments. Thus, in some embodiments, the stepped surfaces of a platform may be vertically offset from each other. Moreover, the stepped surfaces may also be horizontally offset from each other. For example, in some embodiments, the higher stepped surfaces may be spaced further away horizontally from the semiconductor stack 104 compared to the lower stepped surfaces. In some embodiments, the first platform 106 and the second platform 108 may each have one or more steps at the same height measured from the top planar surface 110 of substrate 102. The stepped surfaces, in some embodiments, may be generally parallel to each other and to the top planar surface 110 of substrate 102.

In some embodiments, there are a plurality of through-vias 112 extending through the first and second platforms 106, 108 respectively. In some embodiments, each through-via 112 may extend from one of the stepped surfaces to the substrate 102 to provide a conductive pathway through one of platforms 106, 108, and each through-via 112 may be oriented generally perpendicular to the top planar surface 110 of substrate 102. In some embodiments, a step of one of platforms 106, 108 may include a plurality of through-vias 112. The through-vias 112 may be configured to establish electrical communication between one or more of the semiconductor dies 104a-104l and the substrate 102. The through-vias 112 may be electrically connected to the substrate 102. In some embodiments, the through-vias 112 are embedded within the respective platforms 106, 108 and exposed at one end such that they may be electrically connected to the substrate 102.

In some embodiments, the platforms 106, 108 are configured to minimize and/or reduce a required diameter of through-vias 112 extending therethrough. Each platform 106, 108 may be formed of one or more sections stacked one on top of another. Each section of a platform 106, 108 may be comprised of a conductive layer 109 and a dielectric layer 111. Dielectric layer 111 may be made from, for example, an organic material, the same material as the substrate 102 and/or a ceramic material according to some embodiments. The conductive layer 109 and dielectric layers 111 of a respective section may be fixedly coupled to one another via an adhesive or any other fastening means known to those skilled in the art. In this manner, each platform 106, 108 may be formed of an alternating series of conductive layers 109 and dielectric layers 111. For example, each platform 106, 108 may be formed of a first conductive layer 109, a dielectric layer 111 mounted to the top of the first conductive layer 109, a second conductive layer 109 mounted directly on top of the dielectric layer 111 and so on. In some embodiments, the conductive layers 109 allow for the redistribution of signals among the layers and connect the vias 112. In some embodiments the conductive layers 109 may be comprised of a plurality of conductive traces electrically isolated and/or spaced from one another. In some embodiments the vias 112 may comprise a series of electrically connected sub-vias, each sub-via extending between adjacent conductive layers 109. The series of electrically connected sub-vias may be arranged in a staggered manner, generally linear manner, or a combination thereof. In some embodiments, one or more passive components (e.g., resistors, capacitors, inductors) may be mounted on a platform 106, 108 and electrically connected to the substrate 102 by a through via 112.

In some embodiments, the number of sections included in a respective platform 106, 108 may be dependent upon a desired height of said platform 106, 108. For example, the first platform 106 may be formed of five sections stacked one on top of another and the second platform 108 may be formed of three sections resulting in the total height of the first platform 106 being greater than the total height of the second platform 108. In some embodiments, the vertical thickness of each conductive layer 109 may be generally the same and the vertical thickness of each dielectric layer 111 may also be generally the same. In some embodiments, the uppermost dielectric layer 111 may have a vertical thickness that is less than or greater than the vertical thickness of the dielectric layers 111 positioned directly below it. By providing a series of sections comprised of conductive layers 109 and dielectric layers 111 the required diameter of the through-vias 1112 extending therethrough may be minimized and/or reduced. For example, in an instance where the platforms 106, 108 are formed of a continuous piece of dielectric material, the required diameter of the through-vias 112 passing therethrough may be greater than when there are conductive layers 109 between adjacent dielectric layers 111. In some embodiments, the diameter of the through-vias 112 may be between about 2 microns to about 20 microns. In some embodiments, the diameter of the through-vias 112 may be about 10 microns.

There may be one or more bond pads 114 coupled to the respective first and second platforms 106, 108 and configured to facilitate electrical communication between the stack of semiconductor dies 104 and the through-vias 112. In some embodiments, the bond pads 114 are exposed at surfaces of the first and second platforms 106, 108 and each bond pad 114 is electrically connected to one or more of the through-vias 112. Each bond pad 114 may be exposed at a stepped surface of the respective first and second platforms 106, 108. For example, the first platform 106 may include a first stepped surface 106a, a second stepped surface 106b, and a third stepped surface 106c. There may be bond pads 114 exposed at one or more of the first, second and third stepped surfaces 106a-106c and at least one through-via 112 is electrically connected to each of the bond pads 114. In some embodiments, there are one or more bond pads 114 exposed at each of the first, second and third stepped surfaces 106a-106c. In some embodiments, first, second and/or third stepped surfaces 106a-106c includes a set of bond pads 114 that are arranged in one or more rows on the respective stepped surface. The second platform 108 may include a first stepped surface 108a, a second stepped surface 108b and a third stepped surface 108c. There may be additional bond pads 114 exposed at one or more of the first, second and third stepped surfaces 108a-108c and at least one through-via 112 electrically connected thereto. In some embodiments, there are bond pads 114 exposed at the second and third stepped surfaces 108b-108c. In some embodiments, the first stepped surface 108a may be omitted. The bond pads 114 exposed at a respective stepped surface 106a-106c and/or stepped surfaces 108a-108c may be generally aligned with one another in at least one direction. For example, the bond pads 114 exposed at the third stepped surface 106c may be arranged along a generally straight line or single column. In other embodiments, the bond pads 114 may be arranged along two parallel lines or two columns.

In some embodiments, there may be more than one through-via 112 electrically connected to a single bond pad 114. For example, and as illustrated in FIG. 1B, there are three through-vias 112 electrically and mechanically connected to a single bond pad 114 exposed at the third stepped surface 106c of the first platform 106. In some embodiments, one or more bond pads 114 may have a number of through-vias 112 electrically connected thereto that is different from one or more other bond pads 114. For example, a bond pad 114 exposed at the third stepped surface 108c of the second platform 108 may have a single through-via 112 electrically connected thereto whereas the bond pad 114 exposed at the third stepped surface 106c of the first platform 106 has three through-vias 112 electrically connected thereto.

There may be a plurality of bond wires 116 electrically connecting one or more of the semiconductor dies included in the stack 104 to the through-vias 112 extending through the first and second platforms 106, 108 respectively. For example, there may be a first set of bond wires 116 electrically connecting semiconductor dies 104c-104d, and 104i-1041 to through-vias 112 extending through the first platform 106 and there may be a second set of bond wires 116 electrically connecting semiconductor dies 104e-104h to the through-vias 112 extending through the second platform 108. The bond wires 116 may be electrically connected to and extend between respective bond pads 114 and die bond pads 115 exposed at a surface of the respective semiconductor dies. In this manner, the bond wires 116 may electrically connect a respective semiconductor die (e.g., at least one of semiconductor dies 104a-1041) to the one or more through-vias 112 electrically connected to a respective bond pad 114. The bond pads 114 and die bond pads 115 may be comprised of a conductive material. In some embodiments, the pitch P1 of the bond pads 114 may be less than a pitch P2 of the die bond pads 115. In some embodiments, the pitch P1 is at least half the pitch P2. In some embodiments, the pitch P2 is between about 80 microns to about 120 microns. In some embodiments, the pitch P1 is between about 80 microns to about 120 microns.

In some embodiments, a semiconductor die may be electrically connected, via bond wires 116, to bond pads 114 that are located on the stepped surface that is closest in height to the position of the semiconductor die relative to substrate 102. In some embodiments, die bond pads 115 from different semiconductor dies in the stack 104 may be connected, via the bond wires 116, to different bond pads 114 on the same stepped surface. In some embodiments, a particular stepped surface may include bond pads 114 that connect to two adjacent semiconductor dies in stack 104. For example, as shown in FIGS. 1A and 1B, die bond pads 115 from semiconductor dies 104c and 104d may connect to bond pads 114 on first stepped surface 106a, die bond pads from semiconductor dies 104i and 104j may connect to bond pads 114 on second stepped surface 106b, and die bond pads 115 from semiconductor dies 104k and 104l may connect to bond pads 114 on third stepped surface 106c. Meanwhile, continuing with this illustrated example, die bond pads from semiconductor dies 104e and 104f may connect to bond pads 114 on second stepped surface 108b of second platform 108, and die bond pads from semiconductor dies 104g and 104h may connect to bond pads 114 on third stepped surface 108c of second platform 108.

In some embodiments, certain semiconductor dies that are positioned at or near the bottom of stack 104 may be connected to bond pads directly on substrate 102 rather than on first and second platforms 106, 108. For example, in some embodiments, there are one or more substrate bond pads 118 electrically connected to the substrate 102. The substrate bond pads 118 may be electrically connected to the electrical interface of the substrate 102. As such, the substrate bond pads 118 may act as a set of electrical contact means for transmitting and receiving a plurality of electrical signals. In some embodiments, the substrate bond pads 118 are electrically connected to the substrate 102 and mounted directly on a top surface 110 of the substrate 102. In some such embodiments, unlike bond pads 114, substrate bond pads 118 are not positioned on first or second platforms 106, 108, and substrate bond pads 118 are not connected to through-vias 112. In some embodiments, the substrate bond pads 118 is positioned between a platform (e.g., the first platform 106) and the stack of memory dies 104. There may be bond wires 116 electrically connecting the substrate bond pads 118 to at least one semiconductor die included in the stack 104. For example, in some embodiments, there is a bond wire 116 electrically connecting the bottom most semiconductor die of the stack 104 (e.g., semiconductor die 104a) to a respective substrate bond pad 118. In some embodiments, the two bottom-most semiconductor dies included in the stack 104 are electrically connected to substrate bond pads 118 by corresponding bond wires 116. For example, each of semiconductor dies 104a and 104b may be electrically connected to respective substrate bond pads 118 by bond wires 116 extending therebetween.

In some embodiments, the total number of different stepped surfaces included in platforms 106, 108 may be equal to half of the number of semiconductor dies in stack 104. In some embodiments, the total number of different stepped surfaces included in platforms 106, 108 may be at least half of the number of semiconductor dies in stack 104. In some embodiments, the total number of different stepped surfaces included in platforms 106, 108 may be equal to or at least half of the number of semiconductor dies in stack 104, minus one. In some embodiments, the total number of different stepped surfaces included in a platform 106, 108 may be equal to or less than the number of sub-stacks included in the die stack 104. For example, in FIG. 1A-1B there are three sub-stacks and the total number of stepped surfaces for each platform 106, 108 respectively is three.

In some embodiments, by providing platforms 106, 108 having stepped surfaces spaced at different heights above the substrate 102, the length of the bond wires 116 extending between a respective stepped surface and the semiconductor dies included in the stack 104 may be reduced or minimized and/or reduced. For example, there may be first and second bond wires 116a, 116b electrically connecting one or more of the semiconductor dies included in the stack 104 to the first and second through-vias 112a, 112b. The first bond wire 116a may be electrically connected to the first through-via 112a and to a first semiconductor die, which in this example is semiconductor die 104c. Further to this example, the second bond wire 116b may be electrically connected to the second through-via 112b and to a second semiconductor die, which in this example is semiconductor die 104e. In this manner, the semiconductor dies 104c and 104e may be in electrical communication with the substrate 102 via bond wires 116a, 116b and through-vias 112a, 112b. As such, the length of the first and second bond wires 116a, 116b is less than the length of bond wires needed to directly connect the semiconductor dies to the substrate 102.

The inductance of bond wires increases with the length of the wire (e.g., as a bond wire gets longer the inductance of that wire becomes greater). As inductance increases, the noise in electrical signals (e.g., power signals, ground signals, I/O signals) increases as well. However, a through-via 112 having generally the same length as a bond wire 116 may have a lower inductance than that of bond wire 116. As such, by electrically connecting the bond wires 116 to through-vias 112 that extend upwardly from the substrate 102 through the platforms 106, 108, the required length of the bond wires 116 is minimized and/or reduced thereby reducing the total inductance and improving signal integrity (e.g., reducing signal noise).

In some embodiments, the minimum required length of a bond wire 116 may be directly related to the height of a platform 106, 108 or a stepped surface 106a-106c, 108a-108c thereof. For example, the length of the first bond wire 116a may be directly related to the height H1 of the first stepped surface 106a (e.g., the distance from the stepped surface 106a from the top surface 110 of the substrate 102). As such, the height H1 of the first stepped surface 106a may be selected such that the length of the first bond wire 116a is minimized and/or reduced. In some embodiments, the height of the stepped surfaces 106a-106c, 108a-108c is less than or equal to the height of a bottom-most corresponding semiconductor die on the stack 104 for which a corresponding bond wire 116 is connected. For example, the first bond wire 116a extends between the first stepped surface 106a and the first semiconductor die 104c. There is also another bond wire 116 extending from the first stepped surface 106a to the semiconductor die 104d, which is mounted directly on top of semiconductor die 104c. As such, in relation to the first stepped surface 106a, the bottom-most die on the stack is the first semiconductor die 104c, in this example, for which a corresponding bond wire (e.g., bond wire 116a) is connected. As a further example, in relation to the second stepped surface 106b, the semiconductor die 104i may be the bottom-most semiconductor die 104 on the stack for which a corresponding bond wire 116 is connected. The first stepped surface 106a may have a height H1 that is less than or equal to the height H2 of the semiconductor die 104c. In other embodiments, the height H1 may be +/−about 10% of the height H2. In some embodiments, the height H1 is between about 0.75*H2 to about 0.95*H2.

In some embodiments, the semiconductor device package 100 of the present disclosure is configured to reduce the risk of electrical shorts circuits from occurring. For example, there may be a third through-via 112c electrically connected to the substrate 102 and extending through the first platform 106. The third through-via 112c may be electrically connected to a bond pad 114 exposed at the second stepped surface 106b. The third through-via 112c may be electrically connected to a third bond wire 116c and the third bond wire 116c may be electrically connected to a third semiconductor die, in this example semiconductor die 104i, on the stack 104. At least a portion of the third bond wire 116c may be spaced away from (e.g., vertically above) the first bond wire 116a and/or second bond wire 116b. In some embodiments, the entirety of the third bond wire 116c is positioned above the first bond wire 116a. As such, the distance between the first and second stepped surfaces 106a, 106b of the first platform 106 may provide a vertical offset between the first and third bond wires 116a, 116c. In this manner, the bond wires 116a, 116c may not directly contact one another and the risk of an electrical short occurring between the bond wires 116a, 116c may be reduced.

In some embodiments, the semiconductor device package 100 of the present disclosure is configured to reduce the amount of load (e.g., power, amps) on an upper-most die included in the die stack 104 or any sub-stack thereof. For example, and as illustrated in FIGS. 1A-1B, there is a single set of bond wires 116 connected to each semiconductor die 104a-104l. The bond wires 116 may not include a wire loop connecting to one or more adjacent semiconductor die on the stack 104. In this manner, any increases in inductance as caused by the increasing length of a bond wire electrically connected to multiple dies on a stack is reduced thereby eliminating, or at least reducing, a load experienced by the top-most die connected to that bond wire. For example, each die 104a-104l may have a bond wire 116 connected to only the corresponding die 104a-104l such that each bond wire 116 only carries a load for the corresponding die 104a-104l as opposed to bond wires in conventional die stacks that carry a load to multiple dies (e.g., between two to eight dies).

By providing the first and second platforms 106, 108, through-vias 112 extending therethrough and the bond wires 116 electrically connected thereto, the semiconductor device package 100 of the present disclosure may be configured to improve power and signal integrity, reduce the load on a top-most die of the stack 104, and reduce the risk of electrical short circuits from occurring as discussed above.

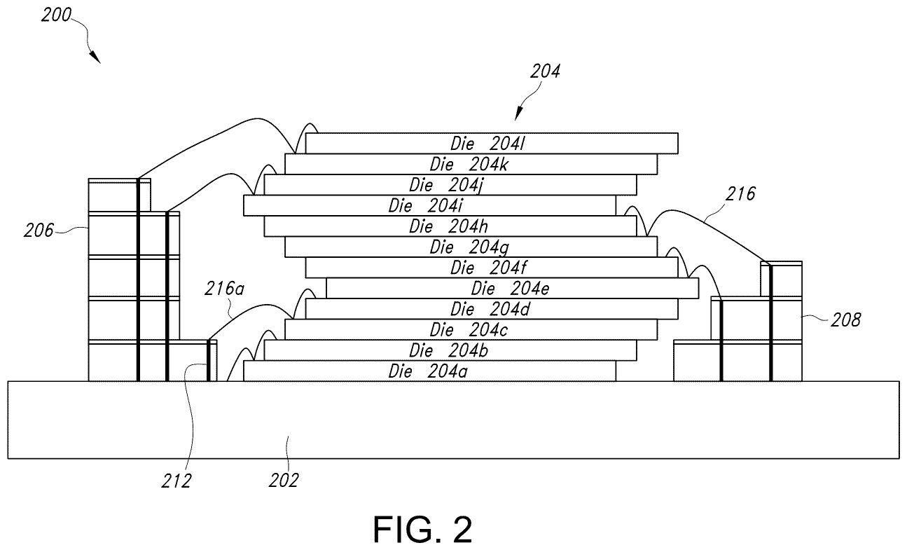

Referring to FIG. 2, there is shown another embodiment of a semiconductor device package, generally designated 200, in accordance with an exemplary embodiment of the present disclosure. The semiconductor device package 200 may be generally the same as package 100 described above with regards to FIGS. 1A-1B, except that the package 200 may include bond wires 216 electrically connecting two adjacent semiconductor dies on the stack 204. The semiconductor device package 200 may include a substrate 202 generally the same as substrate 102, a stack 204 of semiconductor dies 204a-204l generally the same as stack 104, a first platform 206 generally the same as platform 106, and a second platform generally the same as platform 106. There may be a first bond wire 216a electrically connected to a through-via 212. The first bond wire 216a may be different from the first bond wire 116a in that the bond wire 216a of package 200 is electrically connected to a first semiconductor die 204c and to an adjacent semiconductor die 204d. In this manner, the package 200 may include fewer through-vias 212 than package 100. For example, each through-via 212 may be electrically connected to a corresponding bond wire 216 that is electrically connected to two adjacent semiconductor dies (e.g., dies 204c and 204d, dies 204e and 204f, dies 204g and 204h, dies 204i and 204j, and dies 204k and 204l). As such, the number of required through-vias 212 may be reduced as compared to package 100.

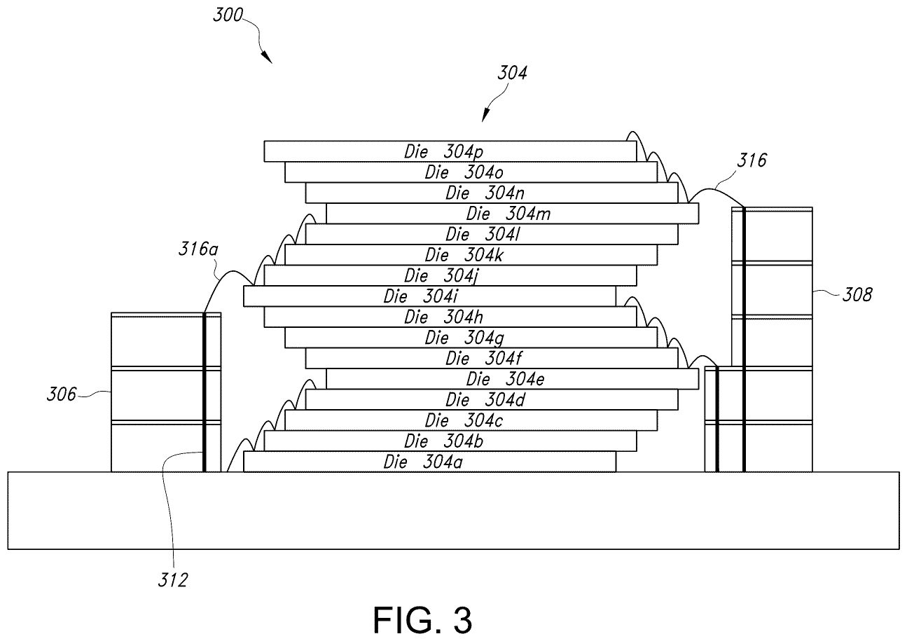

Referring to FIG. 3, there is shown another embodiment of a semiconductor device package, generally designated 300, in accordance with an exemplary embodiment of the present disclosure. The semiconductor device package 300 may be generally the same as package 100 described above with regards to FIGS. 1A-1B, except that the package 300 may include bond wires 316 electrically connected to at least two adjacent semiconductor dies on the stack 304. The semiconductor device package 300 may include a substrate 302 generally the same as substrate 102. The semiconductor device package 300 may include a stack 304 of semiconductor dies 304a-304p generally the same as stack 104 except that the stack 304 includes more dies (e.g., sixteen dies) than stack 104. There may be a first bond wire 316a electrically connecting a first semiconductor die, which, in this example is semiconductor die 304i, to a through-via 312 extending through the first platform 306. The first platform 306 may be similar to the first platform 106 except that it may include fewer stepped surfaces. For example, the first platform 306 includes a single stepped surface. The first bond wire 316a may be electrically connected to the first semiconductor die 304i and at least two adjacent semiconductor dies. For example, and as illustrated in FIG. 3, the first bond wire 316a is electrically connected to dies 304i-3041. In some embodiments, the first bond wire 316a is electrically connected to a sub-stack of semiconductor dies included in the stack 304. For example, semiconductor dies 304a-304d may form a first sub-stack, dies 304e-304h may form a second sub-stack, dies 304i-304l may form a third sub-stack, and dies 304m-304p may form a fourth sub-stack. The semiconductor dies in each sub-stack may be electrically connected to each other. Each of the first, second, third, and fourth sub-stacks may be electrically connected to a corresponding bond wire 316 that is electrically connected to a corresponding through-via 312. In this manner, the semiconductor device package 300 may include fewer through-vias 312 than package 100 and/or package 200. In some embodiments, the bottom-most first sub-stack including semiconductor dies 304a-304d may be connected directly to the substrate via bond wires rather than to through-vias 312 in platforms 306 or 308. In some embodiments, the total number of different stepped surfaces included in platforms 306, 308 may be equal to or at least the number of sub-stacks of semiconductor dies in stack 304. In some embodiments, the total number of different stepped surfaces included in platforms 306, 308 may be equal to or at least the number of sub-stacks of semiconductor dies in stack 304, minus one.

It will be appreciated by those skilled in the art that changes could be made to the exemplary embodiments shown and described above without departing from the broad inventive concepts thereof. It is understood, therefore, that this invention is not limited to the exemplary embodiments shown and described, but it is intended to cover modifications within the spirit and scope of the present invention as defined by the claims. For example, specific features of the exemplary embodiments may or may not be part of the claimed invention and various features of the disclosed embodiments may be combined. The words “right”, “left”, “lower” and “upper” designate directions in the drawings to which reference is made. Unless specifically set forth herein, the terms “a”, “an” and “the” are not limited to one element but instead should be read as meaning “at least one”. As used herein, the term “about” may refer to +/−10% of the value referenced. For example, “about 9” is understood to encompass 8.1 and 9.9.

It is to be understood that at least some of the figures and descriptions of the invention have been simplified to focus on elements that are relevant for a clear understanding of the invention, while eliminating, for purposes of clarity, other elements that those of ordinary skill in the art will appreciate may also comprise a portion of the invention. However, because such elements are well known in the art, and because they do not necessarily facilitate a better understanding of the invention, a description of such elements is not provided herein.

Further, to the extent that the methods of the present invention do not rely on the particular order of steps set forth herein, the particular order of the steps should not be construed as limitation on the claims. Any claims directed to the methods of the present invention should not be limited to the performance of their steps in the order written, and one skilled in the art can readily appreciate that the steps may be varied and still remain within the spirit and scope of the present invention.

What is claimed is:

1. A semiconductor device package comprising:
a substrate;
a stack of semiconductor dies positioned on the substrate and including a first semiconductor die and a second semiconductor die;
a first platform positioned on the substrate;
a second platform positioned on the substrate opposite the first platform such that the stack of semiconductor dies is positioned between the first and second platforms;
a first through-via electrically connected to the substrate and extending through the first platform;
a second through-via electrically connected to the substrate and extending through the second platform;
a first bond wire electrically connecting the first through-via to the first semiconductor die; and
a second bond wire electrically connecting the second through-via to the second semiconductor die.

2. The semiconductor device package of claim 1, wherein the first platform includes a first stepped surface, a second stepped surface vertically offset from the first stepped surface, and a first bond pad exposed at the first stepped surface and electrically connected to the first through-via, and wherein the first through-via extends through the first platform from the first bond pad to the substrate.

3. The semiconductor device package of claim 2, wherein the first platform includes a second bond pad exposed at the second stepped surface, and a third through-via electrically connected to the substrate and the second bond pad, and
wherein the third through-via extends through the first platform from the second bond pad to the substrate.

4. The semiconductor device package of claim 3 further comprising:
a third semiconductor die included in the stack of semiconductor dies, the third semiconductor die positioned above the first and second semiconductor dies; and
a third bond wire electrically connecting the third semiconductor die to the third through-via.

5. The semiconductor device package of claim 4, wherein at least a portion of the third bond wire is positioned vertically above the first bond wire and does not directly contact the first bond wire.

6. The semiconductor device package of claim 1, wherein the first and second platforms include a series of sections stacked one on top of another, each section comprising a conductive layer and a dielectric layer.

7. The semiconductor device package of claim 1 further comprising:
a bond pad exposed at a surface of the first platform, the first bond wire being electrically connected to the bond pad; and
two or more through-vias electrically connected to the bond pad and the substrate.

8. The semiconductor device package of claim 1, wherein the first platform has a total height that is greater than the second platform.

9. The semiconductor device package of claim 1, wherein the first platform and second platform are comprised of a material the same as the substrate.

10. The semiconductor device package of claim 1, wherein the stack of semiconductor dies comprise memory dies.

11. The semiconductor device package of claim 1, further comprising:
a substrate bond pad electrically connected to the substrate and positioned between the stack of semiconductor dies and the first platform; and
a bond wire electrically connecting the substrate bond pad to a bottom most semiconductor die included in the stack of semiconductor dies.

12. The semiconductor device package of claim 1, wherein the first bond wire is electrically connected to the first semiconductor die and another semiconductor die adjacent to the first semiconductor die.

13. The semiconductor device package of claim 1, wherein the first bond wire is electrically connected to the first semiconductor die and at least two adjacent semiconductor dies.

14. A semiconductor memory package comprising:
a substrate including a top surface and a bond pad exposed at the top surface;
a stack of semiconductor dies positioned on the top surface of the substrate;
a first platform positioned on the top surface of the substrate, the first platform including a plurality of through-vias electrically connected to the substrate and extending through the first platform;
a second platform positioned on the top surface of the substrate opposite the first platform such that the stack of semiconductor dies is positioned between the first and second platforms, the second platform including a plurality of through-vias electrically connected to the substrate and extending through the second platform; and
a first bond wire connecting a first semiconductor die of the stack to the at least one through-via of the first platform, and a second bond wire connecting a second semiconductor die of the stack to the at least one through-via of the second platform.

15. The semiconductor device package of claim 14, wherein the first platform includes at least two stepped surfaces vertically offset from one another, each of the stepped surfaces including a bond pad electrically connected to one or more of the plurality of through-vias of the first platform.

16. The semiconductor device package of claim 15, wherein at least one of the bond pads there is connected to two or more of the plurality of through-vias of the first platform.

17. The semiconductor device package of claim 14, wherein the first and second platforms include a series of sections stacked one on top of another, each section comprising a conductive layer and a dielectric layer.

18. The semiconductor device package of claim 14, wherein each through-via of the plurality of through-vias has a diameter of about 10 microns.

19. The semiconductor device package of claim 14, wherein the first platform and second platform are comprised of a material the same as the substrate.

20. A semiconductor device package comprising:
a substrate means for providing electrical interconnections between electrical components coupled to the substrate means;
a first platform means for providing a first set of elevated electrical contacts spaced away from the substrate means, the first platform means include a first conduction means extending through the first platform means for electrically connecting the first set of elevated electrical contacts to the substrate means;
a second platform means providing a second set of elevated electrical contacts spaced away from the substrate means, the second platform means including a second conduction means extending through the second platform means for electrically connecting the second set of elevated contacts to the substrate means; and
a stack of storage means each for storing an amount of data, the stack of storage means positioned on the substrate means between the first platform means and the second platform means, the stack of storage means including a first storage means electrically connected to the first set of elevated electrical contacts, and a second storage means electrically connected to the second set of elevated electrical contacts.
